(19) United States
(12) Patent Application Publication
(10) Pub. No.: US 2010/0171118 A1
(43) Pub. Date: Jul. 8, 2010

(54) Junction Field-Effect Transistor Having Insulator-Isolated Source/Drain Regions and Fabrication Method Therefor

(76) Inventors: Samar Kanti Saha, Miltpitas, CA (US); Ashok K. Kapoor, Palo Alto, CA (US)

Correspondence Address: PERKINS COIE LLP, P.O. BOX 1208, SEATTLE, WA, 98111-1208, US

(21) Appl. No.: 12/350,922

(22) Filed: Jan. 8, 2009

(51) Int. Cl. H01L 29/808; H01L 21/337

(52) U.S. Cl. 257/51; 438/186; 257/E29.312; 257/E21.445

(57) ABSTRACT

Junction field-effect transistors (JFETs) having insulator-isolated source/drain regions and fabrication methods therefor are disclosed here. In SOI JFETs and bulk silicon JFETs having junction isolated source and drain regions from the body region, the junction leakage current is one of the leakage components of the off-state leakage current and consequently limits the on-off switching performance. In particular, for short-channel devices (for example, sub-100 nm and/or sub-65 nm devices), the leakage currents are especially pronounced. The techniques herein introduced include JFET with an insulating spacer such that the source and drain regions are insulator isolated from the body region. In one embodiment, the source and drain regions of the transistor are insulator isolated by silicon dioxide thus reducing the source-drain to body junction leakage current and improved on-off performance.

### TECHNICAL FIELD

This invention relates generally to semiconductor devices, and, in particular, to junction field-effect transistors having source and drain regions that are insulator-isolated from the body region of the transistor.

### BACKGROUND

Miniaturization of transistors has enabled the semiconductor industry to achieve higher packing densities and reduced chip costs. However, the industry continues to suffer from the drawbacks of degraded electrical characteristics due to short channel effects (SCE) or reverse short channel effects (RSCE) that arise from shrinkage of critical dimensions in transistors as the critical dimensions of transistors have undergone dramatic reduction (for example, reduction to dimensions below 65 nm).

The short channel effects that cause degradation in device robustness can include but are not limited to, drain-induced barrier lowering (DIBL), off-state leakage current (e.g., sub-threshold leakage), and/or threshold voltage (Vth) roll off. Additionally, short channel devices are more susceptible to punch-through between the source and drain regions with higher drain biases.

In particular, in a bulk or silicon-on-insulator (SOI) junction field-effect transistor (JFET), the source and/or drain regions are junction isolated from the body. As a result, the junction leakage current is one of the major components of the off-state leakage current in a bulk or SOI JFET. Furthermore, the ON/OFF performance such as the switching time and electrical characteristics of a bulk or SOI JFET become limited with continued shrinkage of the critical dimensions, for example, below the 90 nm regime and even more problematic at 65 nm and smaller.

### SUMMARY

Junction field-effect transistors (JFETS) having insulator isolated source/drain regions and fabrication methods therefore.

The methods herein introduced include a JFET with an insulating spacer such that the source and drain regions are insulator isolated from the body region. In one embodiment, the source and drain regions of the transistor are insulator isolated by silicon dioxide thus reducing the source-drain to body junction leakage current and improved on-off performance.

In one aspect, there is provided a junction field effect transistor, including: a substrate having a substantially planar portion and a protruding portion that protrudes away from the substantially planar portion; an insulator layer in contact with the planar portion; an active region layer in contact with at least the insulator layer and the protruding portion; and a gate region disposed in the active region layer; wherein the insulator layer electrically isolates at least a portion of the active region layer from the substrate.

In another aspect, there is provided a junction field effect transistor, including: a substrate having a planar portion and a protruding portion that protrudes substantially vertically from the planar portion of the substrate; an insulator layer in contact with the planar portion of the substrate; a drain diffusion region and a source diffusion region formed in an active region layer; wherein the active region layer is in contact with the insulator layer or the protruding portion of the substrate; and a gate region formed in the active region layer; wherein a depth of one or more of the drain diffusion region and the source diffusion region is such that series resistance to carrier flow is reduced.

In one aspect, there is provided a method of fabricating an insulated source and drain junction field effect transistor, the method including: etching a substrate to form a protruding structure within the substrate; growing an insulator layer in contact with the substrate; etching the insulator layer; depositing a second insulator layer to be in contact with the insulator layer; selectively etching the second insulator layer to form spacers around the protruding structure; forming an active region layer over the insulator layer; patterning the polysilicon layer according to a predetermined location for one or more of, a source region, a drain region, and a gate region; and forming the gate region.

An integrated circuit including a plurality of JFET transistors.

A field effect transistor having an insulated source and drain formed according to the methods described.

An integrated circuit having a plurality of junction field effect transistors having insulated sources and drains formed according to the method.

Other features of the present disclosure will be apparent from the accompanying drawings and from the detailed description which follows.

### BRIEF DESCRIPTION OF THE DRAWINGS

FIG. 1A illustrates an example cross sectional view of a silicon-on-insulator (SOI) substrate, according to one embodiment.

FIG. 1B illustrates an example cross sectional view of the structure after the silicon etch and insulator layer deposition, according to one embodiment.

FIG. 1C illustrates an example cross sectional view of the structure after etching the insulator layer, according to one embodiment.

FIG. 2A illustrates an example cross sectional view of the structure after insulator spacer formation, according to one embodiment

FIG. 2B illustrates an example cross sectional view of the structure after silicon deposition and planarization, according to one embodiment.

FIG. 2C illustrates an example cross sectional view of the structure after gate region formation, according to one embodiment.

FIG. 3A illustrates an example cross sectional view of the structure after polysilicon deposition and patterning to form the gate, source, and drain, according to one embodiment.

FIG. 3B illustrates an example cross sectional view of the structure after nitride deposition and link spacer deposition, according to one embodiment.

FIG. 3C illustrates an example cross sectional view of the structure after filling the gaps between the contacts with insulating material and optional planarization, according to one embodiment.

FIG. 4A illustrates an example cross sectional view of the structure after gate masking for implantation of gate polysilicon, according to one embodiment.

FIG. 4B illustrates an example cross sectional view of the structure after source/drain masking for source/drain implantation, according to one embodiment.

FIG. 4C illustrates an example cross sectional view of the structure after forming the source, gate, and drain contacts, according to one embodiment.

FIG. 5 illustrates an example process flow for fabricating a JFET having insulator isolated source/drain regions, according to one embodiment.

### DETAILED DESCRIPTION

The following description and drawings are illustrative and are not to be construed as limiting. Numerous specific details are described to provide a thorough understanding of the disclosure. However, in certain instances, well-known or conventional details are not described in order to avoid obscuring the description.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

The terms used in this specification generally have their ordinary meanings in the art, within the context of the disclosure, and in the specific context where each term is used. Certain terms that are used to describe the disclosure are discussed below, or elsewhere in the specification, to provide additional guidance to the practitioner regarding the description of the disclosure. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way.

Consequently, alternative language and synonyms may be used for any one or more of the terms discussed herein, and no special significance should be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and is not intended to further limit the scope and meaning of the disclosure or of any example term. Likewise, the disclosure is not limited to various embodiments given in this specification.

Without intent to further limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, all technical and scientific terms used herein have the same meaning as commonly understood by one of ordinary skill in the art to which this disclosure pertains. In the case of conflict, the present document, including definitions will control.

The terminology used in the description presented below is intended to be interpreted in its broadest reasonable manner, even though it is being used in conjunction with a detailed description of certain specific examples of the disclosure. Certain terms may even be emphasized below; however, any terminology intended to be interpreted in any restricted manner will be overtly and specifically defined as such in this Detailed Description section.

Embodiments of the present disclosure include JFETs having insulator isolated source/drain regions and fabrication methods thereof.

Although embodiments of the present disclosure are described with example reference to junction field effect transistors (JFET), bulk silicon JFETS, or SOI JFETs, the application of the novel aspect of the disclosure is not limited as such. Applications of the principles for short channel effect (SCE) or ultra-short channel effect (USCE) suppression disclosed herein to other types of devices of additional or same materials systems (e.g., Si, Ge, GaAs, other III-V systems, and the like) are contemplated and are considered to be within the scope of this disclosure, including but not limited to, metal-semiconductor field effect transistors (MESFETs), Ge/Si FETs, and/or any other semiconductor device whereby the critical dimensions are generally advantageously shrunken (for example, below the 90 nm regime).

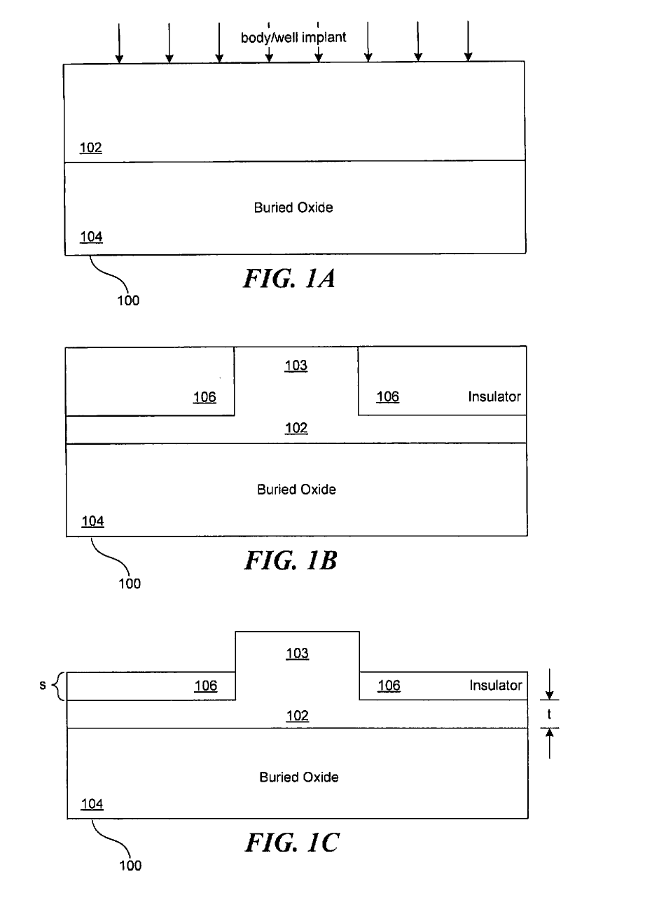

FIG. 1A illustrates an example cross sectional view of a silicon-on-insulator (SOI) substrate 100, according to one embodiment.

The SOI substrate includes a silicon layer 102 and a buried oxide layer 104. The silicon layer is typically although not limited to 300 nm thick and the buried oxide layer 104 is typically although not limited to 150 nm in thickness. Although an SOI substrate is illustrated, embodiments of the techniques herein introduced are also suitable for bulk substrates (e.g., bulk silicon or germanium substrates).

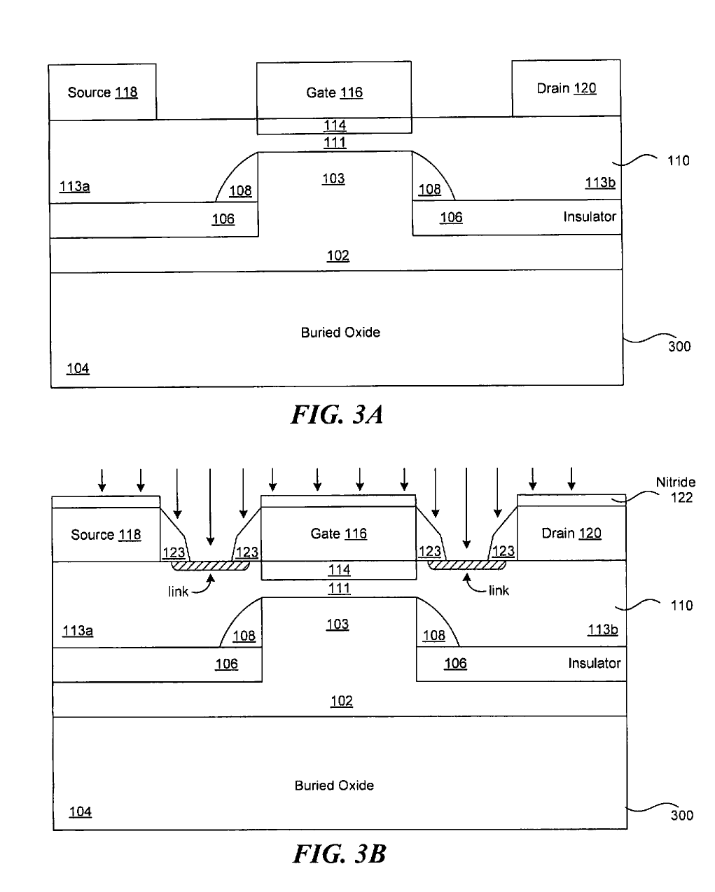

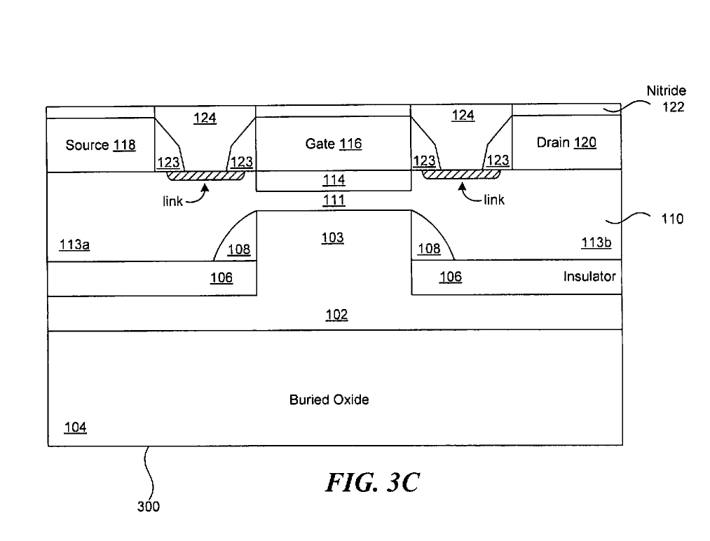

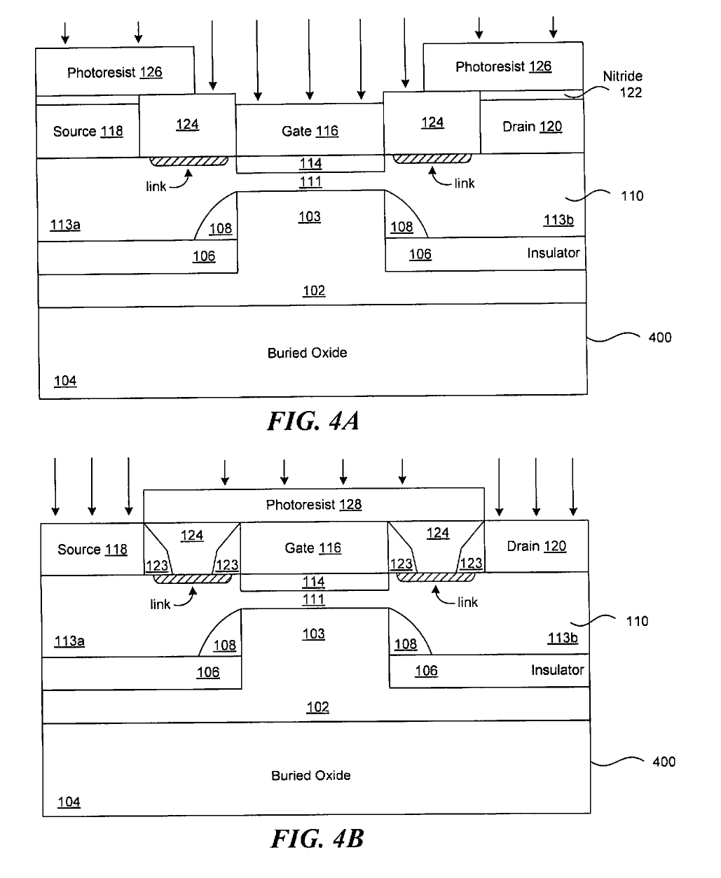

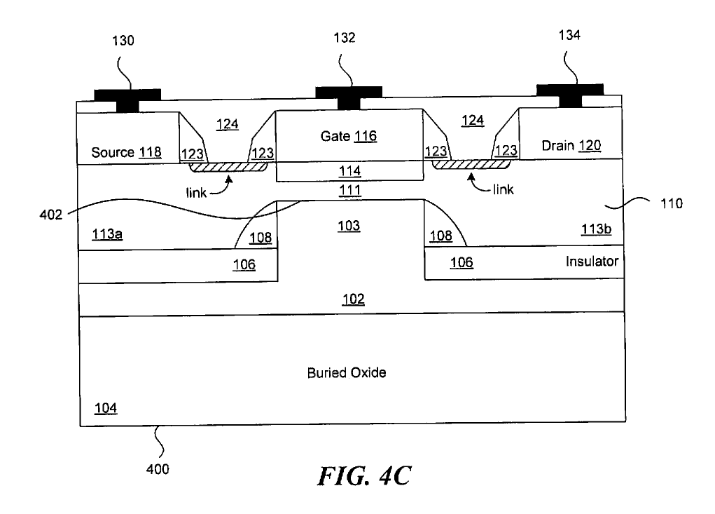

The well implant and body implant regions may be formed in the silicon layer 102 as illustrated in FIG. 1A. The well implant can be formed according to any known and/or convenient manner. Generally, an n-well is formed for a p-JFET and a p-well is formed for an n-JFET. The channel region can later be formed in the well along the source and drain regions (e.g., the source 113a and drain 113b in the example of FIG. 3-4). In addition, a body region can be formed in the silicon layer 102. The optional body implantation can be performed according to any known and/or convenient manner. A dopant or impurity level in the body region may be used to adjust the switching voltage and/or other characteristics. Generally, an n-type body region is formed for a p-JFET and a p-type body-region is formed for an n-JFET.

FIG. 1B illustrates an example cross sectional view of the SOI substrate 100 after the silicon etch having insulator layer deposition, according to one embodiment.

In accordance with one embodiment, the silicon layer 102 is etched such that a fin structure or protruding portion 103 extending outward from the silicon layer 102 is formed. The protruding portion 103 can be rectangular shaped as illustrated in the example of FIG. 1B. In alternate embodiments, the protruding portion 103 can be triangular shaped, pyramid shaped, round, or any other practical or convenient physical shape.

The depth of the fin structure or protruding portion 103 is typically although not limited to 200 nm in thickness and the thickness of the surrounding silicon 102 is etched to a thickness “t” that is typically although not limited to a range between about 80 nm and 120 nm, and more usually about 100 nm. In one embodiment, an insulating layer 106 is deposited over the etched silicon 102. For example, the insulating layer 106 may be silicon dioxide.

FIG. 1C illustrates an example cross sectional view of the SOI substrate 100 after etching the insulator layer 106, according to one embodiment. The insulator layer 106 can be etched around the fin structure 103 of the silicon layer 102 to a predetermined thickness “s”. The thickness “s” of the remaining insulator layer 106 is typically between but not limited to the range between 100 nm to 150 nm and more usually in the range between about 90 nm and 100 nm. In general, the thickness of the insulating layer is such that the threshold voltage of the silicon/silicon-dioxide/silicon layer under drain bias is higher than the supply voltage to prevent a parasitic MOS device from turning on.

The insulator layer 106 is etched such that the protruding portion (e.g., fin structure) 103 of the silicon layer 102 protrudes from or above the height of insulator layer 106.

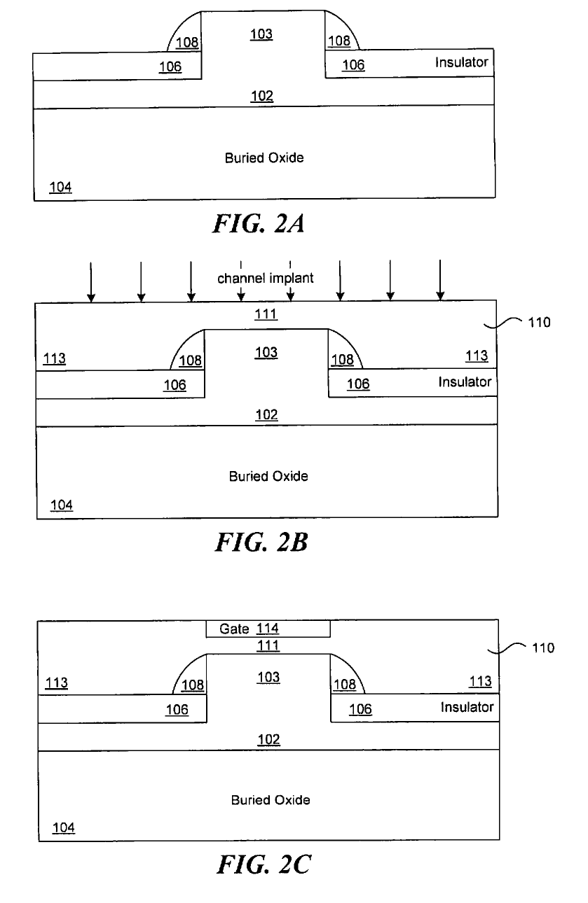

FIG. 2A illustrates an example cross sectional view of the structure after insulator spacer formation, according to one embodiment. The insulating spacers 108 are generally formed around the protruding fin structure 103 for insulating the fin structure 103 from the source/drain regions. The insulating spacers 108 can be formed by depositing another layer of insulating material over the device structure as illustrated in FIG. 1C and removing the insulating material previously deposited on the device except for the regions 108 around the protruding portion 103. In one embodiment, the spacers are formed from silicon dioxide. In an alternate embodiment, the spacers are formed with an additional layer of nitride (e.g., silicon nitride).

FIG. 2B illustrates an example cross sectional view of the structure after silicon deposition and planarization, according to one embodiment. Another layer of semiconductor 110 (e.g., a silicon containing material) is deposited on the structure after spacer 108 formation. The semiconductor layer 110 includes amorphous portions 113 that are adjacent to and in contact with the insulator layer 106 and a crystalline region 111 that is adjacent to and in contact with the top of the fin structure 103.

Furthermore, the channel region 111 is formed via a channel implantation step as illustrated in FIG. 2B. The channel region 111 may be formed between the source and drain regions (e.g., the source 113a and drain 113b in the example of FIG. 3-FIG. 4) according to any known and/or convenient manner, for example, by dopant diffusion in the semiconductor layer 110. For an n-JFET or a p-JFET, the channel depth is generally approximately 20-30 nm although other depths may be implemented, without deviating from the novel aspects and features of the embodiments.

For an nJFET, n-type dopants are used for channel formation. For a p-JFET, p-type dopants are used for channel formation. By way of example but not limitation, in a silicon based device, materials with five valence electrons such as phosphorus and/or arsenic can be used to for n-type doping and materials with three valence electrons such as boron and/or gallium can be used for p-type doping. In one embodiment, the channel doping density is typically although not limited to within the range of 5e¹⁸ to 5e⁹ cm⁻³. The channel doping density is generally tuned to the thickness of the semiconductor layer 110.

FIG. 2C illustrates an example cross sectional view of the structure after gate region 114 formation, according to one embodiment. It may be appreciated that the amorphous portions form over regions of the insulator layer 106 and the crystalline region 111 forms in regions adjacent to the silicon layer 102 from which fin region or protrusion 103 is formed owing to the respective presence or absence of crystalline structure to guide further ordered crystal alignment and growth. In addition, well and channel masking is generally performed at this stage to implant impurities.

FIG. 3A illustrates an example cross sectional view of the structure after polysilicon deposition and patterning to form the gate 114, 116, source 113a, 118, and drain 113b, 120, according to one embodiment. The polysilicon can be deposited and etched. The polysilicon is left where the source, gate, and drain are to be formed. Note that the gate region 114 is implanted in the silicon layer 113 whereas the gate 116 is polysilicon.

FIG. 3B illustrates an example cross sectional view of the structure after nitride deposition 122 and link spacer 123 formation, according to one embodiment.

In one embodiment, the link regions are formed. For example, a link mask is deposited after the nitride layer 122 is deposited and etched to open up the link regions. Impurities are then implanted into the link regions to enhance the availability of carriers. The nitride mask blocks the link implant from the gate region. In one embodiment, link spacers 123 are formed around the source 118, drain 120, and gate regions 116. Link spacers 123 are generally comprised of insulators (e.g., oxides, nitrides and/or a combination of oxides and nitrides) and can isolate the source, gate, and drain regions from the doped channel to decrease parasitic capacitance (e.g., gate-capacitance). Although the link spacers 123 are optional elements, their presence can help reduce off-state current by reducing high electric fields near the gate-edge.

FIG. 3C illustrates an example cross sectional view of the JFET structure 300 after filling the gaps between the gate 114, 116, source 113a, 118, and drain 113b, 120, with insulating material 124 and optional planarization, according to one embodiment.

In one embodiment, the gaps between 116, 118, and 120 are filled with oxide 124 by initially depositing a layer of silicon dioxide and removing the silicon dioxide except at the gaps 124 between the source/gate and the drain/gate, respectively. After the gaps are filled with silicon dioxide, the device surface is (optionally) planarized by chemical-mechanical polishing.

FIG. 4A illustrates an example cross sectional view of the JFET structure 400 after gate masking implantation of gate polysilicon, according to one embodiment. Photoresist 126 can be deposited and then patterned to expose the gate region 116. The gate region polysilicon 116 is then implanted with impurities and is usually highly doped with p-type impurities in an n-JFET and n-type impurities in a p-JFET.

FIG. 4B illustrates an example cross sectional view of the JFET structure 400 after source/drain masking for source/drain implantation, according to one embodiment. Photoresist 128 is deposited and patterned to expose the source region 118 and the drain region 120. The source 118 and drain region 120 polysilicon can then be implanted with impurities. The impurity profile diffuses through source 118 and drain 120 deep into the amorphous silicon region 113 to form source 113a and drain 113b regions. In an n-JFET the source and drain polysilicon layers are generally highly doped with n-type impurities and in a p-JFET with p-type impurities.

FIG. 4C illustrates an example cross sectional view of the JFET 400 after forming the source 130, gate 132, and drain terminals 134, according to one embodiment.

The JFET 400 advantageously includes contacts including, a source terminal 130, a gate terminal 132, and a drain terminal 134. The JFET 400 further includes a doped region 110 in which the channel region 111 (for example an n-channel for an n-JFET and a p-channel for a p-JFET) may be formed along the source region 113a and the drain region 113b in the semiconductor layer 110 (e.g., silicon containing layer). The gate region 114 is electrically coupled to the gate terminal (gate electrode, gate contact) 132 that is operable to modulate a depletion width in the channel region 111.

The body region of the JFET 400 is generally comprised of a semiconducting material such as for example, a silicon containing material. The body region generally includes the planar portion 102 and the fin or protruding portion 103. The semiconducting material may include a silicon containing material or other semiconducting material such as but not limited to a material containing silicon, germanium, a silicon compound, a germanium compound, doped silicon, doped germanium, and any combination or alloy of two or more of these. In one embodiment, the substrate includes substantially planar portion 102 and a fin portion 103 that protrudes away from the substantially planar portion 102.

In one non-limiting embodiment, the substrate generally comprises substantially of, although it not limited to, bulk-silicon. The substrate can also be silicon-on-insulator (SOI) having a buried oxide layer (e.g., buried oxide layer 104).

The substrate is of a first conductivity type whereas the channel region, source region, and drain regions are of a second conductivity type and the gate region is of a first conductivity type.

In one embodiment, the JFET includes an insulator layer 106 in contact with the planar portion 102 of the substrate. The insulator layer 106 electrically isolates the source 113a and drain 113b regions from the body region 102/103. In some embodiments, alternative types of insulators are used for insulating the source 118 and drain 120 regions from the body 102/103. The types of insulators that can be used include by way of example but not limitation, oxides, nitrides (e.g., silicon nitride), oxide/nitride combination, hafnium oxide, and/or aluminum oxide.

The insulation of the source 113a and drain 113b from the body 102/103 can mitigate or further eliminate the leakage current between the body and the source/drain junction in devices where the source and drain are not insulator isolated. Thus, leakage current is reduced in the insulator isolated JFET 400 relative to the conventional JFETs further improving on/off switching performance.

In one embodiment, the source region 113a is isolated from the body region 102/103 of the JFET 400 by at least one insulator to isolate the source region 113a from the transistor body 102/103 and to improve on-off performance and reduce device switching time. In a further embodiment, the drain region 113b is isolated from the body region 102/103 of the JFET by at least one insulator to isolate the drain region 113b from the transistor body 102/103 and to improve on-off performance and reduce device switching time.

In some instances, the drain region 113b and/or source region 113a optionally but advantageously have deep diffusion regions that are deep into the amorphous layer 113 and provide a reduction to source/drain series resistance over devices with shallower source/drain regions. The deep heavily doped source-drain region enlarges the area through which carriers can travel to conduct current thus effectively decreasing the series resistance to carrier travel. Therefore, the on current (drain current, Id) is increased as a result of the reduction in the source/drain series resistance. The diffusion region depth of the source-drain diffusion region may be within a range of although is not limited to, between about 30 nm to 100 nm and more typically between about 30-60 nm. The on current increases about 5-10% for a junction depth between 30-70 nm. For example the junction depth may be 25, 30, 35, 40, 45, 55, 60, 65, 70, 75, 80, 85, 90, 95, or 100 nm or at intermediate depths between any of these example values, to a maximum of the interface between the amorphous Silicon layer 113 and the oxide insulator layer 106.

In one embodiment, the JFET 400 includes an insulator spacer region (e.g., insulator spacer 108) in contact with the insulator layer 106 and in contact with edges of the fin or protrusion 103. In general, the fin 103 protrudes substantially vertically away from the substantially planar portion 102. The fin portion top 402 is an approximately planar surface aligned parallel to the planar portion 106. In general the insulator spacers 108 are at least 2 nm in width. In general the insulator spacer region is substantially at least 2 nm in width but may typically be between 2-20 nm in width and even more usually between substantially 10-15 nm in width.

The insulator spacers 108 can be in contact with edges of the fin portion 103. The insulator spacers 108 further isolate the source 113a and drain 113b from the body 102/103 in particular from the fin portion 103 of the body 102/103 thus providing further suppression of the leakage current between the source/drain and the body 102/103 by shifting the carrier depletion edge away from the gate edge. Approximately 10% reduction in leakage can be achieved. Short channel effects can thus be mitigated by reducing the overall leakage current (e.g., off-state leakage at zero gate bias and non-zero drain bias) in the JFET 400 with insulators. For example, the off-state leakage current per unit width can be between a range of about 10-100 pA/um, thus exhibiting an improvement from 100-1000 pA/um in non-insulator isolated devices and transistors. This represents an improvement of about 10% as compared to the convention devices and JFET transistors. Short channel effects can include but are not limited to, threshold voltage (Vth) roll off and drain induced barrier lowering (DIBL). Short channel effects increase the off state current as the transistors are scaled down. Reduction of SCE in part due to spacers improves the scalability of JFETs beyond the 60 nm with lower off state current.

In one embodiment, the active region layer 110 of the JFET 400 is in contact with at least the insulator layer 106 and the fin or protrusion portion 103. The active region layer 110 may include amorphous material, single-crystalline material, or a combination of amorphous and single-crystalline material. For example, the active region layer 110 can include substantially amorphous-material 113 in contact with the insulator layer 106 and substantially single-crystalline material in contact with a top surface 402 of the fin portion 103.

In one embodiment, the substantially amorphous-material in contact with the insulator layer 106 comprises amorphous silicon and the substantially single-crystalline material in contact with a top surface 402 of the vertical fin portion 103 comprises substantially single-crystalline silicon. The crystalline alignment of the single crystal silicon formed on the fin portion top surface 402 is established by the underlying crystalline silicon structure of the fin portion 103. The source 113a and drain I 13b regions are generally formed in the amorphous-material 113 of the active region layer 110. The channel region 111 can be disposed in the single crystalline material between the drain in the single-crystalline material. The gate region 114 may also be disposed in the single-crystalline material.

Furthermore, the JFET 400 may optionally include a link region coupling the source region 113a to the channel region 111, wherein the link region is more highly doped than the channel region and/or a second link region coupling the drain region 113b to the channel region, wherein the link region is more highly doped than the channel region 111. In general, the doping density of the link region is approximately between about 10×-40× of the channel region doping density and more usually between about 10×-20× of the channel region doping. Although embodiments of insulator isolated source/drain JFET are illustrated as having a silicon-on-insulator substrate, it is appreciated that the insulator isolated source/drain JFET can similarly be adapted for a bulk material substrate (for example, the bulk material substrate may include, but is not limited to silicon, germanium, silicon/germanium, GaAs, etc.).

Additionally, an SOI-based insulator isolated source/drain JFET (e.g., JFET 400) can have a partially or fully depleted body. In one embodiment, the JFET 400 has a thin body region such that it is fully depleted at zero gate bias. A thin body region is generally, although not limited to, a thickness of between 20 nm and 50 nm and more typically between about 25-35 nm. In one non-limiting embodiment, a thin body JFET has a body thickness of 30 nm. The fully depleted body SOI JFET has additional performance benefits. Since the body is fully depleted or substantially fully-depleted during the off-state (e.g., with zero gate bias), the off-state leakage current can be suppressed due to the depletion of mobile carriers. Furthermore, the switch on time is decreased thus also improving AC characteristics of the transistor.

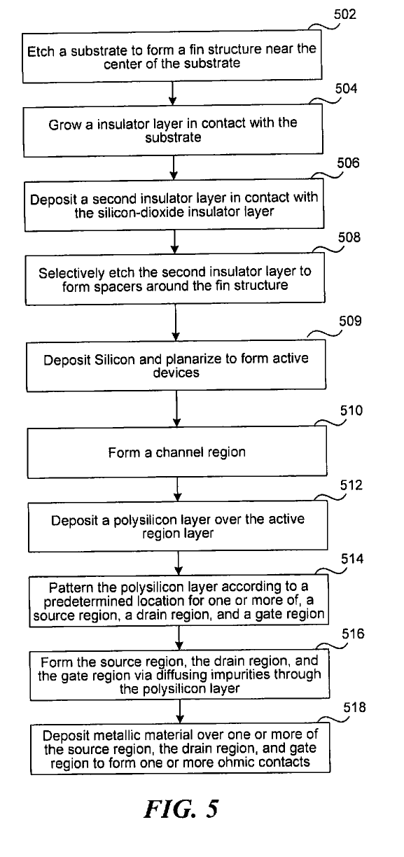

FIG. 5 illustrates an example JFET fabrication method or process flow for fabricating a JFET having insulator isolated source/drain regions, according to one embodiment.

In step or process 502, a substrate is etched to form a fin or otherwise protruding structure. The fin structure is generally protruding from the near the center of the substrate and includes the body region of the JFET to be formed. In general, “near the center” refers to a region of the substrate that includes or almost includes the midpoint location along the length of the substrate between the source and drain regions. The substrate can be a bulk semiconductor material including but not limited to bulk silicon, bulk germanium, silicon/germanium compound, GaAs, etc. In addition, the substrate can be silicon-on-insulator and the silicon portion of the SOI is etched to form the fin structure. Further, the well regions and body regions are formed via dopant implantation.

In step of process 504, a source/drain insulator layer in contact with the substrate is grown. The insulator layer can include any type of insulating material including but not limited to oxides and nitrides such as silicon dioxide and/or silicon nitride. The thickness of the insulator layer can be anywhere between 100 nm to 150 nm and more usually in the range between about 90 nm and 100 nm. The thickness of the insulator layer should be sufficient for electrically insulating the source and/or drain regions from the body, in general, of the device.

In step or process 506, a second insulator layer in contact with the source/drain insulator layer is deposited. The insulator layer can include any type of insulating material including but not limited to oxides and nitrides such as silicon dioxide and/or silicon nitride.

In step or process 508, the second insulator layer is selectively etched to form spacers around the fin or protruding structure. The thickness of the or each insulator spacer is substantially at least 2 nm wide but may typically be between 2-20 nm wide and even more usually between substantially 10-15 nm wide.

The thickness of the insulator spacer should generally be sufficient for electrically insulating the source and/drain regions from the body of the device, in particular, from the fin structure portion of the device.

In step or process 509, a Silicon layer 110 is deposited and planarized to form the active and passive devices.

In step or process 510, the channel region is formed. The channel region may be formed according to any known and/or convenient manner, for example, by dopant diffusion in the silicon containing layer of the substrate such as of the SOI substrate. For an n-JFET or p-JFET, the channel depth is generally between about—20-50 nm and more usually between approximately 25-30 nm although other depths may be implemented, without deviating from the novel aspects and features of the embodiments.

For an n-JFET, n-type dopants are used for channel formation. For a p-JFET, p-type dopants are used for channel formation. By way of example but not limitation, in a silicon based device, materials with five valence electrons such as phosphorus and/or arsenic can be used to for n-type doping and materials with three valence electrons such as boron and/or gallium can be used for p-type doping. In one embodiment, the channel doping density is typically although not limited to within the range of 5e¹⁸ cm⁻³ to 5e¹⁹ cm⁻³.

In step or process 512, polysilicon is deposited on the device. The polysilicon may be doped using any suitable technique, such as diffusion, ion implantation, or in-situ doping. For example, in an n-JFET, the polysilicon may be selectively doped using n-type impurities. When a p-JFET is constructed the polysilicon may be selectively doped using p-type impurities.

In step or process 514, the polysilicon layer is defined. The polysilicon may be defined via any selective etching process (e.g., plasma etch, chemical etch, dry etch, wet etch, or other processes known in the art or convenient) to form the source, gate, and/or drain contacts. The etching process may involve forming a mask to expose appropriate portions of the polysilicon.

In step or process 516, the gate/source/drain regions are formed, for example, via diffusing impurities through the polysilicon layer. For example, the gate region may be formed according to any known and/or convenient manners, such as dopant diffusion through the polysilicon deposition defining the gate location. For an n-type JFET or p-type JFET, the gate junction depth is generally between 5 nm and 20 nm and more usually between 10-15 nm although other implantation depths may be implemented. The source/drain/gate length is generally 60 nm each however alternate dimensions may be implemented. In one embodiment, the source/drain/gate region doping density is approximately 1e²⁰/cm³-2e²⁰/cm³. The source and drain regions may be formed according to any known and/or convenient manners, for example, by the diffusion of dopants through a corresponding polysilicon depositions. For an n-type JFET or a p-type JFET, the source/drain diffusion regions depth are generally between 40 nm and 100 nm and more usually between the range of 70-75 nm although other implantation depths may be implemented, and typically to a maximum of the insulating layer interface 106.

In step or process 518, metallic material is deposited over one or more of the source region, the drain region, and gate region to form one or more ohmic contacts. Alternatively, the contacts may be formed with highly doped polysilicon.

Dielectric sidewall spacers are optionally formed about the polysilicon gate for mitigating high fields between the gate and the channel. For p-JFET or n-JFET devices, each sidewall spacer can be any thickness but is more generally approximately anywhere up to about 15 nm along the length of the device. The sidewall spacers may include two layers. More particularly, the sidewall spacers include a first layer of silicon dioxide immediately adjacent to the polysilicon followed by a layer of silicon nitride. In one embodiment, the sidewall spacers include a single layer sidewall material of, for example, silicon dioxide.

From here, the remainder of JFET is formed using suitable fabrication techniques. For example, at least depositing a metallic material over one or more of the source region, the drain region, and gate region to form one or more ohmic contacts, and forming the metal interconnects.

Methods for operating a JFET (n-JFET and/or p-JFET) and the related principles of operations (e.g., in the enhancement mode and the depletion mode) are well known to those skilled in the art and are not further described here. In one embodiment, the n-JFET operates in the enhancement mode, or otherwise referred to as the normally-off mode. The inventive semiconductor devices and structures operating in these modes have enhanced operating characteristics and performance over conventional devices and structures, including by way of example, but not limitation, reduced off-state leakage current and other implications thereof.

Having now described various aspects, features, and no-limiting embodiments, attention is now directed to particular non-limiting examples.

In one non-limiting example, there is provided a junction field effect transistor, including: a substrate having a substantially planar portion and a protruding portion that protrudes away from the substantially planar portion, an insulator layer in contact with the planar portion; an active region layer in contact with at least the insulator layer and the protruding portion; and a gate region disposed in the active region layer; wherein the insulator layer electrically isolates at least a portion of the active region layer from the substrate.

In one non-limiting example, the junction field effect transistor further including an insulator spacer region in contact with the insulator layer and in contact with edges of the protruding portion.

In one non-limiting example, in the junction field effect transistor, the protruding portion protrudes substantially vertically away from the substantially planar portion, and the insulator spacer region is in contact with edges of the protruding portion.

In one non-limiting example, in the junction field effect transistor, the active region layer includes: substantially amorphous-material in contact with the insulator layer; and substantially single-crystalline material in contact with a top surface of the protruding portion.

In one non-limiting example, in the junction field effect transistor, the substrate includes a silicon containing material.

In one non-limiting example, in the junction field effect transistor, the substantially amorphous-material in contact with the insulator layer includes amorphous silicon and the substantially single-crystalline material in contact with a top surface of the vertical protruding portion includes substantially single-crystalline silicon; and wherein crystalline alignment of the single crystal silicon formed on the protruding portion top surface is established by the underlying crystalline silicon structure of the protruding portion.

In one non-limiting example, in the junction field effect transistor, the protruding portion top surface is a substantially planar surface aligned parallel to the planar portion.

In one non-limiting example, in the junction field effect transistor, the silicon containing material includes silicon, germanium, a silicon compound, a germanium compound, doped silicon, doped germanium, and any combination of two or more of these.

In one non-limiting example, the junction field effect transistor further including: a drain region and a source region formed in the substantially amorphous-material of the active region layer; and a channel region disposed in the substantially single-crystalline material.

In one non-limiting example, in the junction field effect transistor, the silicon containing material includes a body region.

In one non-limiting example, in the junction field effect transistor, the source region is isolated from the body region of the transistor by at least one insulator to isolate the source region from the transistor body and to improve on-off performance and reduce device switching time.

In one non-limiting example, in the junction field effect transistor, the drain region is isolated from the body region of the transistor by at least one insulator to isolate the drain region from the transistor body and to improve on-off performance and reduce device switching time.

In one non-limiting example, in the junction field effect transistor, the gate region is electrically coupled to a gate electrode that is operable to modulate a depletion width in the channel region.

In one non-limiting example, in the junction field effect transistor, the substrate includes substantially of bulk silicon.

In one non-limiting example, in the junction field effect transistor, the substrate includes buried oxide.

In one non-limiting example, in the junction field effect transistor, the insulator layer includes substantially of silicon dioxide.

In one non-limiting example, the junction field effect transistor further including a link region coupling the source region to the channel region, wherein the link region is more highly doped than the channel region.

In one non-limiting example, the junction field effect transistor further including a second link region coupling the drain region to the channel region, wherein the link region is more highly doped than the channel region.

In one non-limiting example, in the junction field effect transistor, a doping density of the link region is substantially 10×-50× of a channel region doping density.

In one non-limiting example, in the junction field effect transistor, the substrate is of a first conductivity type.

In one non-limiting example, in the junction field effect transistor, the channel region, source region, and drain regions are of a second conductivity type and the gate region is of a first conductivity type.

In one non-limiting example, in the junction field effect transistor, the insulator spacer region includes, one or more of, silicon dioxide, nitrides, oxide/nitride combination, hafnium oxide, or aluminum oxide.

In one non-limiting example, in the junction field effect transistor, the insulator spacer region is substantially at least 2 nm thick.

In one non-limiting example, in the junction field effect transistor, the insulator spacer region is between 10-15 nm thick.

In one non-limiting example, in the junction field effect transistor, one or more of the drain region and source region have diffusion regions.

In one non-limiting example, in the junction field effect transistor, the junction depth of the source-drain diffusion regions are within a range of 20-50 nm.

In one non-limiting example, in the junction field effect transistor, the junction depth of the diffusion regions are substantially 30 nm.

In one non-limiting example, in the junction field effect transistor, the diffusion region lowers series resistance in the JFET and increases drain current.

In one non-limiting example, in the junction field effect transistor, the drain diffusion region and the source diffusion region are formed in the active region layer.

In one non-limiting example, in the junction field effect transistor, the off-state leakage current is not dominated by junction leakage current and on-off switching performance is not limited by such junction leakage current for sub 100 nm JFET devices.

In one non-limiting example, in the junction field effect transistor, the source and drain regions are isolated from a body region by at least one insulator to isolate these source and drain regions from the transistor body and to improve on-off performance and reduce device switching time.

In one non-limiting example, in the junction field effect transistor, the at least one insulator includes the insulator layer in contact with the planar portion of the substrate, and the insulator spacer region.

In one non-limiting example, in the junction field effect transistor, the source and drain regions are isolated from the body by the at least one insulator thus suppressing the source-drain to body junction leakage and mitigating short channel effects by reducing leakage current for the device.

In one non-limiting example, in the junction field effect transistor, the short-channel effects includes drain-induced barrier lowering (DIBL).

In one non-limiting example, in the junction field effect transistor, the leakage current is reduced with zero gate bias and a non-zero drain bias.

In one non-limiting example, in the junction field effect transistor, the off-state leakage current is between substantially 10-100 pA/um.

In one non-limiting example, in the junction field effect transistor, the body region is partially depleted at zero gate bias.

In one non-limiting example, in the junction field effect transistor, the body region is fully depleted at zero gate bias.

In one non-limiting example, in the junction field effect transistor, the protruding portion includes a fin structure.

In another non-limiting example, there is provided a junction field effect transistor, including: a substrate having a planar portion and a protruding portion that protrudes substantially vertically from the planar portion of the substrate; an insulator layer in contact with the planar portion of the substrate: a drain diffusion region and a source diffusion region formed in an active region layer; wherein the active region layer is in contact with the insulator layer or the protruding portion of the substrate; and a gate region formed in the active region layer; wherein a depth of one or more of the drain diffusion region and the source diffusion region is such that series resistance to carrier flow is reduced.

In one non-limiting example, in junction field effect transistor further including, an insulator spacer region in contact with the insulator layer and in contact with the protruding portion of the substrate.

In one non-limiting example, in the junction field effect transistor, the active region layer includes: amorphous-material in contact with the insulator layer: and single-crystalline material in contact with a top surface of the protruding portion.

In one non-limiting example, the junction field effect transistor further including a channel region formed in the single-crystalline material between the drain diffusion region and the source diffusion region.

In one non-limiting example, in the junction field effect transistor, the gate region is electrically coupled to a gate electrode that is operable to modulate a depletion width in the channel region.

In one non-limiting example, in the junction field effect transistor, the insulator spacer region is substantially at least 2 nm thick.

In one non-limiting example, in the junction field effect transistor, the insulator spacer region is between 10-15 nm thick.

In one non-limiting example, in the junction field effect transistor, the insulator layer includes substantially of silicon dioxide.

In one non-limiting example, in the junction field effect transistor, the depth of the diffusion region is within a range of 20-50 nm.

In one non-limiting example, in the junction field effect transistor, the series resistance to carrier flow is reduced by between substantially 5%-10%.

In another non-limiting example, there is provided a method of fabricating an insulated source and drain junction field effect transistor, the method including: etching a substrate to form a protruding structure within the substrate; growing an insulator layer in contact with the substrate; etching the insulator layer; depositing a second insulator layer to be in contact with the insulator layer; selectively etching the second insulator layer to form spacers around the protruding structure; forming an active region layer over the insulator layer; patterning the polysilicon layer according to a predetermined location for one or more of, a source region, a drain region, and a gate region; and forming the gate region.

In one non-limiting example of the method, the insulator layer is etched to a predetermined thickness.

In one non-limiting example of the method, the predetermined thickness is substantially between 30-50 nm.

In one non-limiting example of the method, the active region layer includes: amorphous-material in contact with the insulator layer; and single-crystalline material in contact with a top surface of the protruding structure.

In one non-limiting example of the method, the method further including: forming a channel region of a first conductivity type in the active region layer; depositing a polysilicon layer on the channel region; and forming a gate contact; wherein, the gate contact is electrically coupled to the gate region.

In one non-limiting example of the method, the forming the gate contact, includes: masking the polysilicon layer; implanting the polysilicon layer with impurities of a second conductivity type; and etching the polysilicon layer to form the gate contact.

In one non-limiting example of the method, the method further including: performing a thermal drive in to diffuse the impurities from the gate contact into the underlying channel region to form the gate region of the second conductivity type.

In one non-limiting example of the method, the channel region and the gate region are formed by ion implantation of impurities.

In one non-limiting example of the method, the method further including: masking off the gate contact and implanting impurities of the first conductivity type to form the source region and the drain region.

In one non-limiting example of the method, at least one of the source region and the drain region have diffusion regions.

In one non-limiting example of the method, the diffusion regions are formed by ion implantation.

In one non-limiting example of the method, the method further including: forming highly conductive doped link regions of first conductivity type.

In one non-limiting example of the method, the insulator layer includes silicon dioxide.

In one non-limiting example of the method, the protruding structure is formed near a center of the substrate.

In another non-limiting example, there is provided an integrated circuit including a plurality of JFET transistors having any of the structures described herein.

In another non-limiting example, there is provided a field effect transistor having an insulated source and drain formed according to any of the methods described herein.

In another non-limiting example, there is provided an integrated circuit having a plurality of junction field effect transistors having insulated sources and drains formed according to any of the methods described herein.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof, means any connection or coupling, either direct or indirect, between two or more elements; the coupling of connection between the elements can be physical, logical, or a combination thereof. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above detailed description of embodiments of the disclosure is not intended to be exhaustive or to limit the teachings to the precise form disclosed above. While specific embodiments of, and examples for, the disclosure are described above for illustrative purposes, various equivalent modifications are possible within the scope of the disclosure, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed in parallel, or may be performed at different times. Further any specific numbers noted herein are only examples: alternative implementations may employ differing values or ranges.

The teachings of the disclosure provided herein can be applied to other methods, devices, and/or systems, not necessarily to those described above. The elements and acts of the various embodiments described above can be combined to provide further embodiments.

Any patents and applications and other references noted above, including any that may be listed in accompanying filing papers, are incorporated herein by reference. Aspects of the disclosure can be modified, if necessary, to employ the systems, functions, and concepts of the various references described above to provide yet further embodiments of the disclosure.

These and other changes can be made to the disclosure in light of the above Detailed Description. While the above description describes certain embodiments of the disclosure, and describes the best mode contemplated, no matter how detailed the above appears in text, the teachings can be practiced in many ways. Details of the device may vary considerably in its implementation details, while still being encompassed by the subject matter disclosed herein. As noted above, particular terminology used when describing certain features or aspects of the disclosure should not be taken to imply that the terminology is being redefined herein to be restricted to any specific characteristics, features, or aspects of the disclosure with which that terminology is associated.

In general, the terms used in the following claims should not be construed to limit the disclosure to the specific embodiments disclosed in the specification, unless the above Detailed Description section explicitly defines such terms. Accordingly, the actual scope of the disclosure encompasses not only the disclosed embodiments, but also all equivalent ways of practicing or implementing the disclosure under the claims.

While certain aspects of the disclosure are presented below in certain claim forms, the inventors contemplate the various aspects of the disclosure in any number of claim forms. Accordingly, the inventors reserve the right to add additional claims after filing the application to pursue such additional claim forms for other aspects of the disclosure.

What is claimed is:

1. A junction field effect transistor, comprising:
a substrate having a substantially planar portion and a protruding portion that protrudes away from the substantially planar portion of the substrate;
an insulator layer in contact with the planar portion of the substrate;
an active region layer in contact with at least the insulator layer or the protruding portion; and
a gate region disposed in the active region layer.

2. The transistor of claim 1, wherein the insulator layer electrically isolates at least a portion of the active region layer from the substrate.

3. The transistor of claim 2, further comprising an insulator spacer region in contact with the insulator layer and in contact with edges of the protruding portion.

4. The transistor of claim 3, wherein the protruding portion protrudes substantially vertically away from the substantially planar portion; and the insulator spacer region is in contact with edges of the protruding portion.

5. The transistor of claim 2, wherein the active region layer comprises:
substantially amorphous-material in contact with the insulator layer; and
substantially single-crystalline material in contact with a top surface of the protruding portion.

6. (canceled)

7. The transistor of claim 5, wherein:
the substantially amorphous-material in contact with the insulator layer comprises amorphous silicon and the substantially single-crystalline material in contact with a top surface of the vertical protruding portion comprises substantially single-crystalline silicon; and
wherein crystalline alignment of the single crystal silicon formed on the protruding portion top surface is established by the underlying crystalline silicon structure of the protruding portion.

8. (canceled)

9. (canceled)

10. The transistor of claim 5, further comprising:
a drain region and a source region formed in the substantially amorphous-material of the active region layer; and
a channel region disposed in the substantially single-crystalline material.

11. (canceled)

12. (canceled)

13. (canceled)

14. The transistor of claim 10, wherein the gate region is electrically coupled to a gate electrode that is operable to modulate a depletion width in the channel region.

15. (canceled)

16. (canceled)

17. (canceled)

18. The transistor of claim 10, further comprising a link region coupling the source region to the channel region, wherein the link region is more highly doped than the channel region.

19. The transistor of claim 10, further comprising a second link region coupling the drain region to the channel region, wherein the link region is more highly doped than the channel region.

20. (canceled)

21. (canceled)

22. (canceled)

23. (canceled)

24. The transistor of claim 11, wherein the source and drain regions are isolated from a body region by at least one insulator to isolate these source and drain regions from the transistor body and to improve on-off performance and reduce device switching time.

25. The transistor of claim 24, wherein the at least one insulator comprises the insulator layer in contact with the planar portion of the substrate, and the insulator spacer region.

26. The transistor of claim 24, wherein the source and drain regions are isolated from the body by the at least one insulator thus suppressing the source-drain to body junction leakage and mitigating short channel effects by reducing leakage current for the device.

27. (canceled)

28. (canceled)

29. (canceled)

30. The transistor of claim 1, further comprising:
a drain diffusion region and a source diffusion region formed in the active region layer; and
a depth of one or more of the drain diffusion region and the source diffusion region is such that series resistance to carrier flow is reduced.

31. The transistor of claim 30, further comprising, an insulator spacer region in contact with the insulator layer and in contact with the protruding portion of the substrate.

32. The transistor of claim 30, wherein the active region layer comprises:
amorphous-material in contact with the insulator layer; and
single-crystalline material in contact with a top surface or the protruding portion.

33. The transistor of claim 30, further comprising a channel region formed in the single-crystalline material between the drain diffusion region and the source diffusion region.

34. The transistor of claim 30, wherein the gate region is electrically coupled to a gate electrode that is operable to modulate a depletion width in the channel region.

35. (canceled)

36. A method of fabricating a junction field effect transistor, the method comprising:
etching a substrate to form a protruding structure within the substrate;
growing an insulator layer in contact with the substrate;
etching the insulator layer;
depositing a second insulator layer to the in contact with the insulator layer;
selectively etching the second insulator layer to form spacers around the protruding structure;
forming an active region layer over the insulator layer;
patterning the polysilicon layer according to a predetermined location for one or more of, a source region, a drain region, and a gate region; and
forming the gate region.

37. (canceled)

38. (canceled)

39. The method of claim 36, further comprising:
forming a channel region of a first conductivity type in the active region layer;
depositing a polysilicon layer on the channel region;
forming a gate contact; and
wherein, the gate contact is electrically coupled to the gate region.

40. The method of claim 36, further comprising:
forming a channel region of a first conductivity type in the active region layer;
depositing a polysilicon layer on the channel region;
forming a gate contact; and
wherein, the gate contact is electrically coupled to the gate region;
wherein forming the gate contact further comprises:
masking the polysilicon layer;
implanting the polysilicon layer with impurities of a second conductivity type; and
etching the polysilicon layer to form the gate contact.

41. (canceled)

42. (canceled)

43. (canceled)

44. (canceled)

45. (canceled)

46. (canceled)

47. (canceled)

48. (canceled)

49. (canceled)

50. A field effect transistor formed according to the method of claim 36.

51. (canceled)

52. An integrated circuit having a plurality of junction field effect transistors having insulated sources and drains formed according to the method of claim 36.

53. An integrated circuit including a plurality of JFET transistors as in claim 1.

54. (canceled)

55. (canceled)

56. (canceled)

57. (canceled)

58. A method of fabricating a junction field effect transistor, comprising the steps of:
forming a substrate having a substantially planar portion and a protruding portion that protrudes away from the substantially planar portion;
forming an insulator layer in contact with the planar portion;
forming an active region layer in contact with at least the insulator layer and the protruding portion; and
forming a gate region disposed in the active region layer.

59. The method in claim 58, wherein the insulator layer electrically isolates at least a portion of the active region layer from the substrate.

60. The method in claim 58, wherein the protruding portion protrudes substantially vertically from the substantially planar portion of the substrate; and further comprising; forming a drain diffusion region and a source diffusion region in an active region layer; wherein the active region layer is in contact with the insulator layer or the protruding portion of the substrate; wherein a depth of one or more of the drain diffusion region and the source diffusion region is such that series resistance to carrier flow is reduced.

61. The method in claim 58, wherein the insulator layer electrically isolates at least a portion of the active region layer from the substrate.

62. The transistor of claim 6, wherein:
the silicon containing material comprises a body region;
the source region is isolated from the body region of the transistor by at least one insulator to isolate the source region from the transistor body and to improve on-off performance and reduce device switching time;
the drain region is isolated from the body region of the transistor by at least one insulator to isolate the drain region from the transistor body and to improve on-off performance and reduce device switching time; and
the body region is at least partially depleted or fully depicted at zero gate bias.
